(19) United States
(12) Patent Application Publication
(10) Pub. No.: US 2025/0319637 A1
(43) Pub. Date: Oct. 16, 2025

(54) SYSTEM INCLUDING AN ARRAY INCLUDING A HEAT SOURCE AND AN ACTINIC RADIATION SOURCE

(71) Applicant: CANON KABUSHIKI KAISHA, Tokyo (JP)

(72) Inventors: Steven C. SHACKLETON, Austin, TX (US); Seth J. BAMESBERGER, Austin, TX (US); Byung-Jin CHOI, Austin, TX (US); Timothy Brian STACHOWIAK, Austin, TX (US); Niyaz KHUSNATDINOV, Round Rock, TX (US)

(21) Appl. No.: 18/637,153

(22) Filed: Apr. 16, 2024

(51) Int. Cl. B29C 35/08; B29C 35/00; B29C 35/02; B29C 35/16

(52) U.S. Cl. CPC B29C 35/0805; B29C 35/002; B29C 35/16; B29C 2035/0211; B29C 2035/0827

(57) ABSTRACT

A system can include an array of at least one heat source adapted to heat a stack including a superstrate, a substrate, and a polymerizable composition between the superstrate and the substrate, and at least one actinic radiation source adapted to at least photocure the polymerizable composition to form a photocured planarization layer. Implementations of the system can allow more flexibility regarding heating and exposure operations and may allow a system to occupy less area. Separate stations for heating a pre-cured layer of a polymerizable composition and exposing the pre-cured layer is not required. The array of actinic radiation sources and heat sources allow greater flexibility with respect to timing for heating and exposing to actinic radiation the pre-cured layer. The system can be used in a method that forms a photocurable planarization layer from a pre-cured layer of a polymerizable composition.

### FIELD OF THE DISCLOSURE

The present disclosure relates to a system including an array that includes a heat source and an actinic radiation source and a method of using the same.

### RELATED ART

Ink-jet Adaptive Planarization (IAP) is used in microelectronic fabrication. As dimensions of microelectronic components continue to become smaller, processes, including IAP, become more difficult. IAP can be performed such that a polymerizable composition is at a temperature greater than room temperature while the polymerizable composition is exposed to actinic radiation. A need exists for a system designed to allow for heating the polymerizable composition during exposure while still maintaining acceptable throughput when forming the planarization layer.

### SUMMARY

In an aspect, a system can include an array of at least one heat source adapted to emit heat at a peak heating wavelength and heat a stack including a superstrate, a substrate, and a polymerizable composition between the superstrate and the substrate, and at least one actinic radiation source adapted to emit actinic radiation at a peak actinic radiation wavelength and at least photocure the polymerizable composition to form a photocured planarization layer. The peak heating wavelength can be different from the peak actinic radiation wavelength.

In an implementation, the peak heating wavelength is greater than the peak actinic radiation wavelength.

In another implementation, the at least one heat source is adapted to emit heat at a peak heating wavelength in a range from 400 nm to 2500 nm.

In a particular implementation, the peak heating wavelength is in a range from 400 nm to 1100 nm.

In another particular implementation, the peak heating wavelength is in a range from 960 nm to 2500 nm.

In a further particular implementation, the at least one actinic radiation source is adapted to emit actinic radiation at a peak actinic radiation wavelength of at least 10 nm and less than 400 nm.

In another implementation, the at least one heating source includes a plurality of point heat sources.

In still another implementation, the at least one heating source includes at least one resistive heating member.

In yet another implementation, the system further includes a bake station adapted to bake the substrate and the photocured planarization layer; and a controller adapted to receive bake station information and transmit a signal to the at least one heat source based on the bake station information.

In a further implementation, the system of claim 1 further includes a stage adapted to move the substrate; and a first thermal isolation member disposed between the stage and the at least one heat source.

In a particular implementation, the system further includes a cooling means adapted to reduce an amount of heat from the at least one heating source that reaches the stage, wherein the cooling means is disposed between the stage and the first thermal isolation member.

In a more particular implementation, the system further includes a second thermal isolation member, wherein the cooling means is disposed between the first thermal isolation member and the second thermal isolation member.

In another implementation, the system further includes a stage adapted to move the substrate; and a substrate chuck adapted to support the substrate and disposed between the stage and the at least one heat source.

In a particular implementation, the substrate chuck includes a cooling means adapted to reduce an amount of heat from the at least one heating source that reaches the stage.

In a more particular implementation, the substrate chuck further includes a thermal isolation member to reduce an amount of heat from the at least one heating source that reaches the stage.

In another aspect, a method can include heating a stack with at least one heat source to a targeted temperature, wherein the stack includes a substrate, a superstrate, and a polymerizable composition disposed between the substrate and the superstrate. The at least one heat source can emit heat at a peak heating wavelength. An array can include the at least one heat source; and at least one actinic radiation source. The method can further include curing the polymerizable composition to form a photocured planarization layer, wherein curing is performed by exposing the stack to radiation emitted by the at least one actinic radiation source, and the at least one actinic radiation source emits actinic radiation at a peak actinic radiation wavelength. The peak heating wavelength can be different from the peak actinic radiation wavelength.

In an implementation, during warming the stack is disposed on a substrate chuck, the substrate chuck is coupled to a stage, and a temperature of the stage is below a threshold when the stack is at the targeted temperature.

In a particular implementation, the method further includes activating a cooling means that is disposed between the stack and the stage during heating, curing, or both.

In another particular implementation, the method further includes moving the stack while the polymerizable composition is being cured and is at a temperature higher than an ambient temperature.

In another implementation, a dosage of actinic radiation emitted from the at least one actinic radiation source is below a threshold when the polymerizable composition is below the targeted temperature.

In a further implementation, the method further includes baking the substate and the photocured planarization layer at a baking temperature to form a baked planarization layer, wherein during curing, the polymerizable composition is at a desired radiation exposure temperature+/−3° C., wherein the desired radiation exposure temperature is selected at least in part on the baking temperature.

### BRIEF DESCRIPTION OF THE DRAWINGS

Implementations are illustrated by way of example and are not limited to the accompanying figures.

FIG. 1 includes a conceptual view of a portion of a system that can be used in forming a photocured planarization layer from a polymerizable composition.

FIG. 2 includes a conceptual view of another portion of the system of FIG. 1 including post-exposure bake stations.

FIG. 3 includes a cross-sectional view of a portion of a station that includes a radiation head assembly, a substrate chuck, and a positioning stage.

FIG. 4 includes a bottom up view of an array of heat and actinic radiation sources in accordance with an implementation.

FIG. 5 includes a bottom up view of an enlarged portion of the array of FIG. 4.

FIG. 6 includes a bottom up view of the array in accordance with another implementation.

FIG. 7 includes a bottom up view of the array in accordance with still another implementation.

FIG. 8 includes a bottom up view of the array in accordance with yet another implementation.

FIG. 9 includes a bottom up view of the array in accordance with a further implementation.

FIG. 10 includes a bottom up view of the array in accordance with another implementation.

FIG. 11 includes a process flow diagram for forming a baked planarization layer from a polymerizable composition.

FIG. 12 includes an illustration of a cross-sectional view of a positioning stage, a substrate chuck, a substrate, and a dispense head when dispensing droplets of a polymerizable composition over the substrate.

FIG. 13 includes an illustration of a cross-sectional view of a positioning stage, the substrate chuck, and the substrate when a superstrate and a combination of the substrate and the droplets are being moved closer to each other.

FIG. 14 includes an illustration of a cross-sectional view of the positioning stage, the substrate chuck, the substrate, and the superstrate of FIG. 12 after forming a pre-cured layer of the polymerizable composition.

FIG. 15 includes an illustration of a cross-sectional view of the positioning stage, the substrate chuck, the substrate, the superstrate, and the pre-cured layer of FIG. 13 when heating the pre-cured layer.

FIG. 16 includes an illustration of a cross-sectional view of the positioning stage, the substrate chuck, the substrate, the superstrate, and the pre-cured layer of FIG. 13 when heating and exposing the pre-cured layer to actinic radiation.

FIG. 17 includes an illustration of a cross-sectional view of the positioning stage, the substrate chuck, the substrate, the superstrate, and the pre-cured layer of FIG. 13 when exposing the pre-cured layer to actinic radiation.

FIG. 18 includes a timing diagram illustrating when the pre-cured layer is heated and exposed to actinic radiation in accordance with an implementation.

FIG. 19 includes a timing diagram illustrating when the pre-cured layer is heated and exposed to actinic radiation in accordance with another implementation.

FIG. 20 includes a timing diagram illustrating when the pre-cured layer is heated and exposed to actinic radiation in accordance with still another implementation.

FIG. 21 includes a timing diagram illustrating when the pre-cured layer is heated and exposed to actinic radiation in accordance with yet another implementation.

FIG. 22 includes a timing diagram illustrating when the pre-cured layer is heated and exposed to actinic radiation in accordance with a further implementation.

FIG. 23 includes a timing diagram illustrating when the pre-cured layer is heated and exposed to actinic radiation in accordance with another implementation.

FIG. 24 includes a timing diagram illustrating when the pre-cured layer is heated and exposed to actinic radiation in accordance with yet another implementation.

FIG. 25 includes a timing diagram illustrating when the pre-cured layer is heated and exposed to actinic radiation in accordance with still another implementation.

FIG. 26 includes a timing diagram illustrating when the pre-cured layer is heated and exposed to actinic radiation in accordance with a further implementation.

FIG. 27 includes an illustration of a cross-sectional view of the positioning stage, the substrate chuck, the substrate, the superstrate, and the pre-cured layer of FIG. 13 after forming a photocured planarization layer.

FIG. 28 includes an illustration of a cross-sectional view of a substrate chuck and the substrate of FIG. 27 after baking the photocured planarization layer to form a baked planarization layer.

Skilled artisans appreciate that elements in the figures are illustrated for simplicity and clarity and have not necessarily been drawn to scale. For example, the dimensions of some of the elements in the figures can be exaggerated relative to other elements to help improve understanding of implementations of the inventive concepts.

### DETAILED DESCRIPTION

The following description in combination with the figures is provided to assist in understanding the teachings disclosed herein. The following discussion will focus on specific implementations of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which these inventive concepts belon. The materials, methods, and examples are illustrative only and not intended to be limiting. To the extent not described herein, many details regarding specific materials and processing acts are conventional and can be found in textbooks and other sources within the arts.

A system can include an array of at least one heat source and at least one actinic radiation source. The heat source(s) can be adapted to emit heat at a peak heating wavelength and heat a stack including a superstrate, a substrate, and a polymerizable composition between the superstrate and the substrate, and the actinic radiation source(s) can be adapted to emit actinic radiation at a peak actinic radiation wavelength and at least photocure the polymerizable composition to form a photocured planarization layer. The peak heating radiation wavelength can be different from the peak actinic radiation wavelength.

The system can allow more flexibility regarding heating and exposure operations and may allow the system to occupy less area. Separate stations for heating a pre-cured layer of a polymerizable composition and exposing the pre-cured layer is not required. The array of actinic radiation sources and heat sources allow greater flexibility with respect to timing for heating and exposing to actinic radiation the pre-cured layer. Heat sources can be activated before, at the same time of, or after activating the actinic radiation sources. The actinic radiation sources can be deactivated after, at the same time of, or before deactivating the heat sources. After initial heating, heat pulses may be used to help maintain the temperature of the pre-cured layer within a narrower range as compared to heat pulses not being used. The actinic radiation sources, the heat sources, or the actinic radiation sources and heat sources may be adapted to operate at more than one power level. Thus, the amount of actinic radiation, heat, or both may be changed as a function of time.

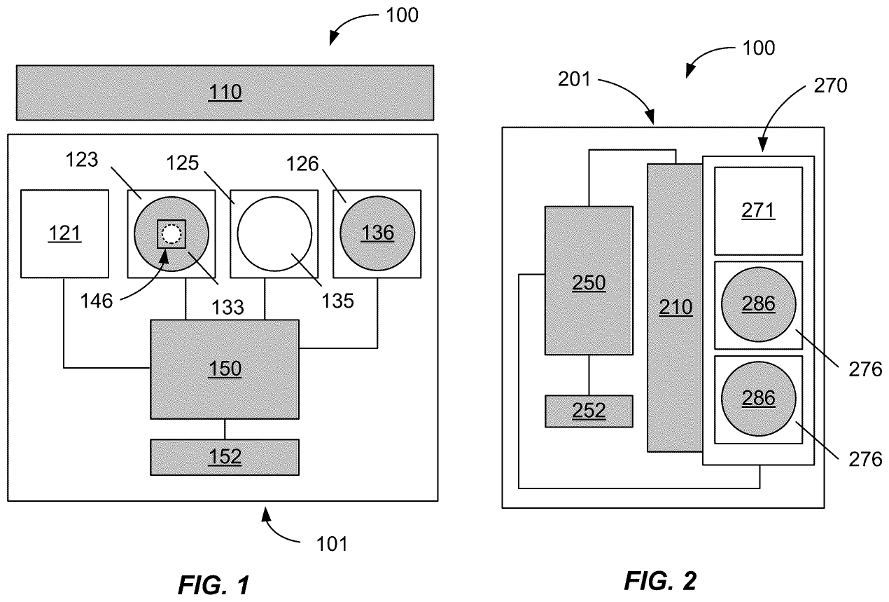

A system 100 illustrated in FIGS. 1 and 2 can be used for the method. The system is well suited for an IAP process. After reading this specification, skilled artisans will be able to determine the number of apparatuses and their corresponding operations when designing a system.

FIGS. 1 and 2 include a conceptual diagram of a system 100 that can be used to form a baked planarization layer from a polymerizable composition. The system 100 can include a cure apparatus 101 and a post-exposure bake apparatus 201 that can be used to bake a photocured planarization layer into the baked planarization layer. The polymerizable composition will be mostly cured before baking. Some curing can occur during the post-exposure baking operation.

The cure apparatus 101 includes a substrate transfer tool 110, a substrate pod 121, a dispense station 123, a planarization head station 125, a heated radiation exposure station 126, a controller 150, and a memory 152. The dispense station 123 can include a substrate chuck 133 that can be coupled to a positioning stage (illustrated in a subsequent figure) that allows the substrate chuck 133 to move during a dispensing operation. Another positioning stage (illustrated in subsequent figures) can be used to move a substrate chuck 136 between the stations 125 and 126. The bake apparatus 201 in FIG. 2 can include a substrate transfer tool 210, a bake unit 270, a controller 250, and a memory 252. The bake unit 270 can include a substrate pod 271 and at least one bake station 276 that can each include a substrate chuck 286.

Many of the previously-mentioned components are described below with respect to the functions that each performs. More details regarding operation of the components, and particularly, the stations 123, 125, 126 and 276, are described in more detail later in this specification with respect to methods of using the systems.

The substrate transfer tool 110 can be adapted to transfer a substrate to or from any of the substrate pod 121, the dispense station 123, the planarization head station 125, and the heated radiation exposure station 126. The substrate transfer tool 210 can be adapted to transfer at least one substrate to or from any of the substrate pod 271 and the bake stations 276. The substrate transfer tools 110 and 210 may be or include at least one component of an Equipment Front End Module (EFEM). The components of the EFEM can include at least one of each of the following: a robot arm, a robot hand adapted for holding substrates, a sensor, a motor for moving the robot arm, another motor for moving the robot arm, and the like. The robot arm can be adapted to move the substrate with or without a layer between stations, for example, to or from the substrate pod 121, the dispense station 123, the planarization head station 125, the heated radiation exposure station 126. The substrate transfer tool 210 in FIG. 2 can be identical to or different from the substrate transfer tool 110 in FIG. 1.

Referring to FIGS. 1 and 2, the substrate pods 121, and 271 can hold a plurality of substrates. An example of a substrate pod is a Front Opening Unified Pod (FOUP) which is defined by industry standards (for example, SEMI E47.1-1106, 2012) as a pod for storing and transporting substrates. The systems described herein include coupling plates, interface holes, and load ports for receiving and transferring substrates to and from one to four substrate pods. A substrate can be removed from the substrate pod 121, processed at stations of the system 100, such as the stations 123, 125, 126, or a combination thereof, and moved to the substrate pod 121 or another substrate pod when processing in the portion of the system 100 illustrated in FIG. 1 is completed. A substrate can be removed from the substrate pod 271, processed at least one of the bake stations 276, and returned to the substrate pod 271 or another substrate pod when baking is completed.

The dispense station 123 can be adapted to receive a substrate and dispense a polymerizable composition over the substrate. When the substrate is over the substrate chuck 133, a dispense head 146 can be used to dispense a polymerizable composition over the substrate. The dispense head 146 can include at least one nozzle that dispenses the polymerizable composition. The dashed line within the dispense head 146 is used to indicate that the polymerizable composition is dispensed along the bottom side of the dispense head 146. A positioning stage (not illustrated in FIG. 1) can be coupled to the substrate chuck 133, and the positioning stage, the dispense head 146, or both can be adapted to move when dispensing the polymerizable composition. More details regarding the polymerizable composition and methods of dispensing and processing the polymerizable composition are described later in this specification. The substrate transfer tool 110 can transfer the substrate and the polymerizable composition overlying the substrate from the dispense station 123 to the substrate chuck 136 after a different positioning stage (not illustrated in FIG. 1) coupled to the substrate chuck 136 is moved to planarization head station 125.

The planarization head station 125 can include a planarization head 135 that is adapted to place a superstrate in contact with the polymerizable composition. The superstrate can be placed in contact with droplets of the polymerizable composition causing droplets of the polymerizable composition to coalesce and form a pre-cured layer of the polymerizable composition. In an implementation, the planarization head 135 can be adapted to remove the superstrate after the polymerizable composition is sufficiently cured. FIG. 1 illustrates the planarization head station 125. In practice, more than one planarization head station can be used. In a non-limiting implementation, a ratio of planarization head stations to heated radiation exposure stations can be 1:1. In another implementation, the ratio may be lower (relatively fewer planarization head stations) or higher (relatively more planarization head stations).

The positioning stage coupled to the substrate chuck 136 can transfer the substrate and the pre-cured layer of the polymerizable composition overlying the substrate from the planarization head station 125 to the heated radiation exposure station 126. In an alternative implementation, a positioning stage can be shared by the stations 123, 125, and 126, rather than having two different positioning stages.

The heated radiation exposure station 126 can be adapted to photocure the polymerizable composition. A pre-cured layer of the polymerizable composition can be exposed to actinic radiation when the pre-cured layer is at an elevated temperature above the ambient temperature. Ambient temperature is the temperature of the room in which a station within an apparatus is located. Thus, the ambient temperature can be the room temperature. For example, the ambient temperature may be in a range from 20° C. to 25° C. The actinic radiation can cause a polymerizable material within the polymerizable composition to polymerize and form a photocured planarization layer. The photocured planarization layer may be further cured at an optional curing station, with or without the superstrate, before being baked.

The positioning stage shared by the stations 125 and 126 can move the substrate chuck, the substrate and the photocured planarization layer from the heated radiation exposure station 126 to the planarization head station 125 where the superstrate can be removed after the radiation exposure operation in the heated radiation exposure station 126 is completed.

The heated radiation exposure stations 126 can be adapted to perform two operations. The heated radiation exposure stations 126 can be adapted to heat the pre-cured layer and expose the pre-cured layer to actinic radiation to form the photocured planarization layer. More details regarding the heat sources, actinic radiation sources, heating and exposing the pre-cured layer to actinic radiation are described later in this specification.

FIG. 1 illustrates the heated radiation exposure station 126. In practice, more than one heated radiation exposure station can be used. When a plurality of heated radiation exposure stations 126 is used, the organization of the heated radiation exposure stations 126 can be planar where heated radiation exposure stations 126 lie along a single plane, may be stacked, or a combination of heated radiation exposure stations 126 lying along a single plane and another combination of heated radiation exposure stations 126 being stacked. Stacking the heated radiation exposure stations 126 can help to reduce the area occupied by the stations 126. The number of heated radiation exposure stations 126 within a stack can be two or more. Due to height constraints within a room where the stations 126 are located and the height of each heated radiation exposure stations, the number of heated radiation exposure stations 126 within a stack may be limited to 9 stations, 7 stations, or 5 stations. The number of stacks can be one or more. The number of stacks may be limited by available floor space within the room in which the cure unit is located. The number of stacks of heated radiation exposure stations 126 may be limited to 9 stacks, 7 stacks, or 5 stacks.

Referring to FIG. 2, the post-exposure bake unit 270 can include the substrate pod 271 and post-exposure bake stations 276 that include substrate chucks 286. The post-exposure bake stations 276 can further polymerize or crosslink the polymerizable composition within the photocured planarization layer due to thermal curing, cause a different reaction of a component within the polymerizable composition, drive out a volatile component within the polymerizable composition, or the like.

The post-exposure bake stations 276 can have a heating means. The heating means for the post-exposure bake stations 276 can be activated to bake the photocured planarization layer. More details regarding the heating means for the post-exposure bake stations 276 are described later in this specification. A direct temperature measurement of the photocured planarization layer may be difficult to obtain. Thus, the temperature of the photocured planarization layer can correspond to a different temperature within the heated radiation exposure station 126. The temperature of the photocured planarization layer may be correlated to the temperature of its corresponding substrate chuck 286 or the substrate or superstrate overlying such substrate chuck 286. A user of the system 100 may control operations using the temperature of the substrate chuck 286, the substrate, or the superstrate because a direct temperature measurement of the photocured planarization layer may not be practical. The temperature used for post-exposure baking may be at least 300° C. The highest processing temperature associated with the post-exposure bake stations 276 may be as high as 500° C.

The previously described operation performed by any particular station may be moved or combined with another station. For example, the dispensing of the polymerizable composition and placement and removal of the superstrate can be performed within the same station. For example, the placement and removal of the superstrate may be performed using a planarization head when present within either of the stations 123 and 126. Thus, the planarization head station 125 is not required in all implementations.

Each of the substrate chucks 133, 136, and 286 can be a vacuum chuck, a pin-type chuck, a groove-type chuck, an electrostatic chuck, an electromagnetic chuck, or the like. The substrate chucks 133, 136, and 286 may be the same type, for example, vacuum chucks, or may be different types. For example, one of the substrate chucks can be a vacuum chuck, and another one of the substrate chucks can be an electrostatic or electromagnetic chuck. Each of the substrate chucks 133, 136, and 286 may or may not have a heating element, a cooling element, or both that can be used to heat or cool a substrate and a layer, and if present, a superstrate overlying the substrate. More details on designs of the substrate chucks are described later in this specification.

The controller 150 is coupled to the memory 152 and can control components within the cure apparatus 101, and the controller 250 is coupled to the memory 252 and can control components within the bake apparatus 201. The controller 150 and the memory 152 are described in more detail below. The description of the controller 150 can apply to the controller 250 and the description of the memory 152 can apply to the memory 252 except as explicitly noted when addressing specific details of the system 100.

If needed or desired, any combination of the controllers 150 and 250 can communicate with each other. For example, one or both controllers 150 and 250 can be used to confirm that a particular lot of substrates with photocured planarization layers at the substrate pod 271 have completed processing within the cure apparatus 101 before the substrates and photocured planarization layers are baked at a post-exposure bake station 276 in the bake unit 270.

The controller 150 and 250 can operate using a computer readable program, optionally stored in memory 152 or 252. Either or both of the controllers 150 and 250 can include a processor (for example, a central processing unit of a microprocessor or microcontroller), a field-programmable gate array (FPGA), an application specific integrated circuit (ASIC), or the like. Either or both of the controllers 150 and 250 can further include internal memory, such as a set of registers, a cache memory, a flash memory, or the like. The controllers 150 and 250 can be within the system 100. In another implementation (not illustrated) of the system, one or both of the controllers 150 and 250 can be at least part of a computer external to the system 100, where such computer is bidirectionally coupled to the system 100.

Any or all of the memories 152 and 252 can include a non-transitory computer readable medium that includes instructions to carry out the actions associated with or between operations. Either or both of the memories 152 and 252 can include a set of registers, a cache memory, a flash memory, a hard drive, or the like. Either or both of the memories 152 and 252 can further include data tables that can be accessed by either or both of the controllers 150 and 250 to assist in determining an operating parameter, for example, a local areal density of the polymerizable composition to be dispensed, a targeted temperature, a radiation exposure temperature, a dose of actinic radiation during at least one radiation exposure operations, a total dose of actinic radiation received by a polymerizable composition for all radiation exposure operations, a post-exposure baking temperature, or another parameter used in the methods as described below. As used herein, the total dose is a sum of the doses used in exposing a polymerizable composition to actinic radiation. In an implementation, the total dose can be the sum of a dose used in forming a photocured planarization layer and another dose used in an optional curing process. The controller can select the targeted temperature associated with the heated radiation exposure based on the post-exposure baking temperature stored in memory.

In another implementation, at least one components, such as the stations 123, 125, 126, and 276, of the system 100 can include a local controller that provides some of the functionality that would otherwise be provided by the controller 150 or 250.

More or fewer controllers and more or fewer memories may be used with respect to the system 100. In another implementation, a single controller can perform all of the functions described with respect to the controllers 150 and 250. Thus, one controller, rather than two controllers, may be used with the system 100. In a further implementation, the controller 150 may control the cure apparatus 101 and the bake apparatus 201, and thus the controller 250 is not required, or the controller 250 may control the cure apparatus 101 and the bake apparatus 201, and thus the controller 150 is not required. In another implementation, a single memory, rather than two memories, may be used with the system 100.

In another implementation, the heated radiation exposure station 126 can be in a different apparatus as compared to the dispense station 123. The planarization head station 125 may be located in the apparatus that includes the heated radiation exposure station 126 or the dispense station 123.

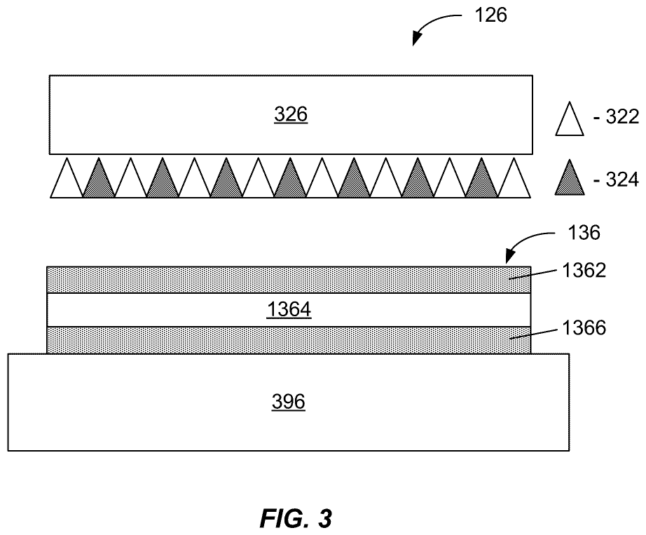

FIG. 3 includes a cross-sectional view of a portion of the system 100 that includes one of the heated radiation exposure stations 126. The substrate chuck 136 is coupled to a positioning stage 396. A radiation assembly 326 can include an array of one or more heat sources and one or more actinic radiation sources. The radiation assembly 326 is described in more detail later in this specification.

The substrate chuck 136 can include a thermal isolation section 1362, a cooling section 1364, and a thermal isolation section 1366. Any or all of the sections 1362, 1364, and 1366 can reduce the amount of heat that reaches the positioning stage 396. The positioning stage 396, the substrate chuck 136, or both may include positioning or other mechanisms that are designed to move to precise locations. Over time, exposure to heat or repeated heating and cooling cycles may cause the positioning or other mechanisms to drift and require recalibration or may cause a feature within the positioning stage 396, the substrate chuck 136, or both to become warped, distorted, or otherwise change in shape.

Either or both of the thermal isolation sections 1362 and 1366 can include a relatively low thermal conductivity material. The relatively low thermal conductivity material can have a thermal conductivity less than 5 W/(m*K). An exemplary material can include a polymer, quartz, zirconia, yttria, cordierite, Vacuum Insulated Panel, or aerogel. The thermal isolation sections 1362 may include an upper surface that that reflects thermal radiation such as a hot mirror, a hot mirror coating, or a hot mirror polish.

In the any of the previous implementations or a different implementation, the surface of the thermal isolation section 1362 facing the radiation head assembly 326 may have a relatively lower contact area with a substrate (not illustrated) that is supported by the thermal isolation section 1362 than the opposite surface that has relatively higher contact area with the cooling section 1364. In the same or different implementation, the surface of the thermal isolation section 1366 facing the positioning stage 396 may have a relatively lower contact area with a positioning stage 396 than the opposite surface that has relatively higher contact area with the cooling section 1364. The thermal isolation section 1366 is optional and may not be present in all implementations. The cooling section 1364 can include a channel or other flow path to allow a cooling fluid to flow through the cooling section 1364. Although not illustrated, the substrate chuck 136 can include lift pins that can raise or lower a substrate with respect to the substrate chuck 136.

The heated radiation exposure station 126 further includes a radiation head assembly 326. The radiation head assembly 326 can include an array of at least one heat source and at least one actinic radiation source. Although the radiation head assembly 326 may include as little as one heat source (with a plurality of actinic radiation sources) or one actinic radiation source (with a plurality of heat sources), subsequent references to the heat sources and actinic radiation source are referred to in the plural to simplify the description of the radiation head assembly 326, even if only one heat source or one actinic radiation source is present. Referring to FIG. 3, the actinic radiation sources can emit actinic radiation 322 to photocure a polymerizable composition, and the heat sources can emit heat 324 to heat the polymerizable composition to a temperature higher than the ambient temperature. Each of the actinic radiation and heat sources may emit radiation at a spectrum of wavelengths, where the radiation can be characterized by a peak wavelength that is the wavelength corresponding to the highest intensity within the spectrum.

The actinic radiation sources can include lamps, light emitting diodes (LEDs), or lasers that can emit actinic radiation that can be at a wavelength or range of wavelengths tailored for activating a photoinitiator within the polymerizable composition. The actinic radiation can have a peak actinic radiation wavelength from 10 nm to 500 nm. The actinic radiation can be ultraviolet radiation having a wavelength in a range from 100 nm to 400 nm, and more particularly, in a range from 200 nm to 400 nm. A supplier of the polymerizable composition may provide a targeted wavelength or a targeted range from wavelengths to be used to photocure the polymerizable composition.

The heat sources lamps, light emitting diodes (LEDs), or heating elements that can emit heat having a peak heating wavelength in a range of 400 nm to 2500 nm. The wavelength to be used for heating may depend in part on principal material with a substrate. The substrate can be a monocrystalline semiconductor wafer or a wafer that includes a combination of a base material, an insulator, and a semiconductor layer, for example, a silicon-on-insulator substrate. Regarding the latter category, the base material makes up most of the mass of the wafer. A lower transmission of the heat can help to reduce the amount of heat flowing to the substrate chuck 136 or the positioning stage 396. In an implementation, the principal material for the substrate can be Silicon (Si). Si has a relatively low transmission of radiation at a wavelength less than 1200 nm. Thus, the heat sources can emit heat at a peak heating wavelength in a range from 400 nm to 1100 nm. In another implementation, heat sources can emit heat at a peak heating wavelength in a range from 500 nm to 900 nm to provide a good balance between intensity of heat emitted (desired) and radiation transmitted through a substrate (undesired). Thus, the heat sources may emit visible light that can heat the substrate. In another implementation, the principal material for the substrate can be the 4H polytype of Silicon Carbide (4H-SiC). A 400 μm thick piece of 4H-SiC can transmit less than 50% of incident radiation at a wavelength greater than 960 nm. Thus, the heat sources can emit heat at a peak heating wavelength in a range from 960 nm to 2500 nm. A shorter wavelength of radiation can be used to heat 4H-SiC provided any one or more of the thermal isolation sections 1362 and 1366 and the cooling section 1364 have a sufficiently robust design to keep the amount of heat reaching sensitive parts of the station 126 at an acceptable level.

The heat sources may emit a relatively broadband or narrow spectrum of radiation. For example, a heat source may emit radiation with a spectrum of 450 nm to 1000 nm. A different type of heat source may emit radiation with a spectrum of 450 nm to 700 nm. A further type of heat source, for example, a light-emitting diode, may emit radiation with a spectrum of 400 nm to 650 nm. If needed or desired, a filter can be located between the heat sources and a workpiece that includes the polymerizable composition to narrow the range of wavelengths of radiation reaching the workpiece. In another implementation, a filter can be located between the workpiece and an observation tool to allow a wavelength or relatively small range of wavelengths to be received by the observation tool. In the same or different implementation, the heat sources may emit heat at a peak heating wavelength that is different from a peak actinic radiation wavelength corresponding to the actinic radiation sources. In a more particular implementation, the peak heating wavelength can be longer than the peak actinic radiation wavelength. In a non-limiting example, the peak heating wavelength may be 700 nm, and the peak actinic radiation may be 300 nm.

The actinic radiation sources may be adapted to only emit one power level of radiation when activated or may be adapted to emit more than one power level of radiation when activated. The heat sources may be adapted to only emit one power level of heat when activated or may be adapted to emit more than one power level of heat when activated.

The radiation exposure station 126 can further include a temperature sensor (not illustrated) within the substrate chuck 136, or a proximity temperature sensor (not illustrated). The temperature sensor within the substrate chuck 136 can be located where it can contact or be in close proximity (for example, within 1 mm) of a substrate when the substrate is located over substrate chuck 136. The proximity temperature sensor can receive near infrared radiation from a substrate, a polymerizable composition, or a superstate to determine a temperature of the substrate, the polymerizable composition, or the superstrate.

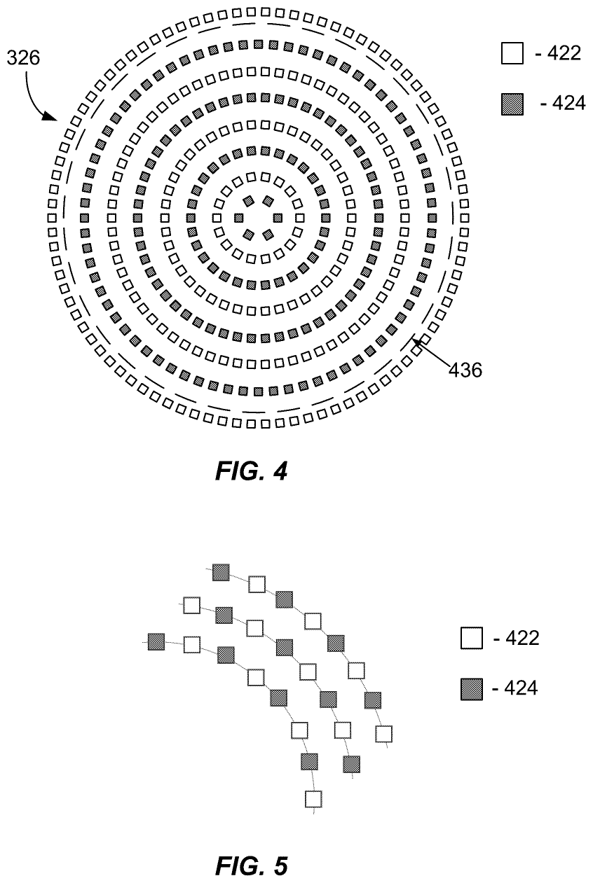

FIG. 4 includes a bottom-up view of a portion of the radiation head assembly 326 that includes actinic radiation sources 422 and heat sources 424. The dashed line 436 corresponds to the shape of a substrate holding surface of the substrate chuck 136. As illustrated in FIG. 4, the actinic radiation sources 422 and the heat sources 424 are arranged in alternating substantially concentric circles, where each circle has all actinic radiation sources 422 and no heat source 424 or has all heat sources 424 and no actinic radiation source 422. In another implementation, at least one actinic radiation source 422 and at least one heat source 424 are located along the same circle. FIG. 5 includes a bottom-up view of a portion of the radiation head assembly 326 that includes alternating actinic radiation sources 422 and heat sources 424 along the circles. In an alternative implementation, the radiation head assembly 326 is incorporated into the planarization head station 125 instead of a separate heated radiation exposure station 126 forming a planarization and heated radiation station. The planarization and heated radiation station includes a radiation head assembly 326 that shines radiation through the planarization head 135.

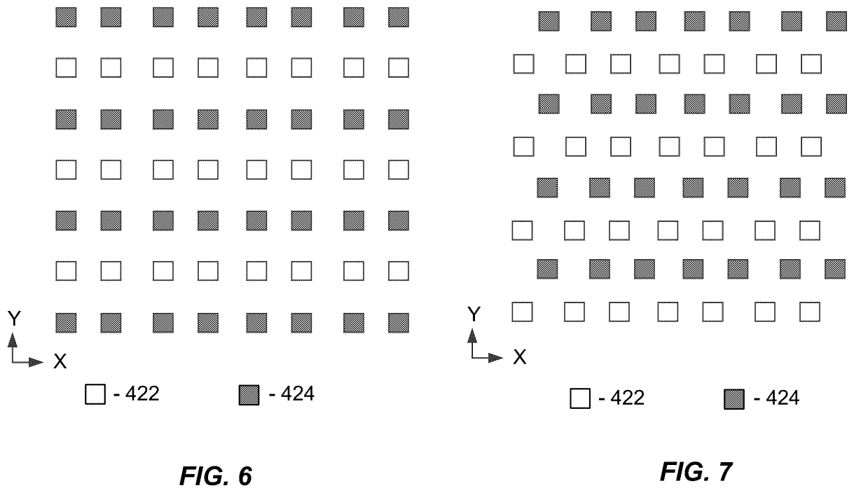

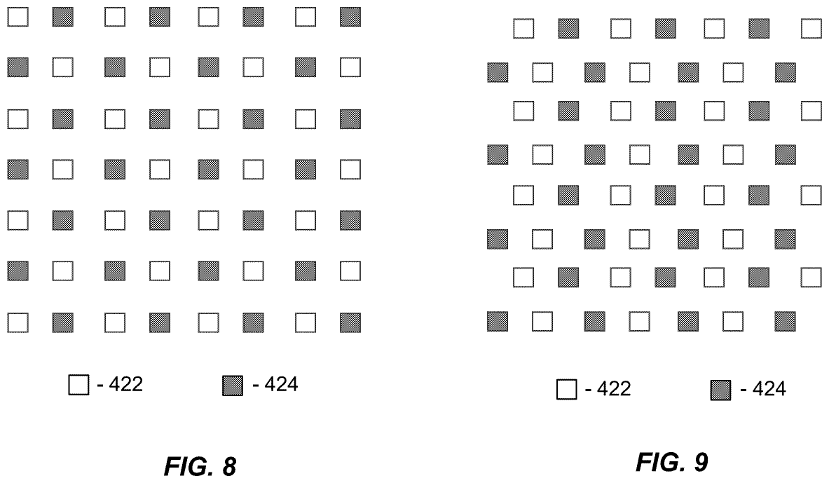

FIGS. 6 and 7 include bottom-up views of portions of the radiation head assemblies that includes alternating rows of actinic radiation sources 422 and heat sources 424. FIG. 6 has a rectilinear pattern of the actinic radiation sources 422 and heat sources 424. FIG. 7 has a hexagonal pattern of the actinic radiation sources 422 and heat sources 424. In FIG. 7, the rows of the heat sources 424 are offset in the X-direction by ½ of the pitch for the actinic radiation sources 422 in their immediately adjacent rows. FIGS. 8 and 9 are similar to FIGS. 6 and 7, respectively except that rows of the actinic radiation sources 422 and rows of the heat sources 424 are replaced by a checkerboard pattern of the actinic radiation sources 422 and the heat sources 424. In FIG. 9, each row of actinic radiation sources 422 and the heat sources 424 are offset in the X-direction by ½ of the pitch for the sources 422 and 424 in its immediately adjacent row.

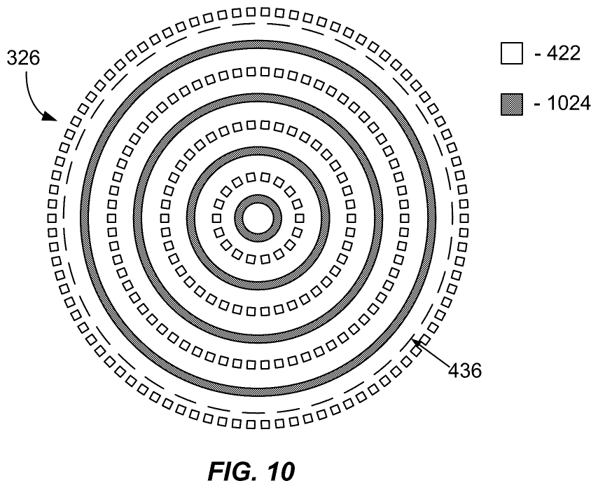

The heat sources can be in the form of heating elements as illustrated in FIG. 10. The organization of the actinic radiation sources 422 is identical to what is illustrated in FIG. 4. The point heat sources 424 are replaced by heat sources 1024. The heat sources 1024 may include resistive wires that can emit heat when current flows through the resistive wires.

Many other patterns for the array of the actinic radiation sources 422 and the heat sources 424 can be used without deviating from the concepts described herein. In an implementation, the numeric ratio of actinic radiation sources 422 to the heat sources 424 can be 1:1 as illustrated in FIGS. 4 to 10. In another implementation, the ratio of the number of actinic radiation sources 422 to the number of heat sources 424 can be different from 1:1. For example, the intensity of radiation emitted by the actinic radiation sources 422 can be significantly different from the intensity of heat emitted by the heat sources 424. The ratio of the number of actinic radiation sources 422 to the number of heat sources 424 can range from 5:1 to 1:5 or from 1:2 to 2:1. For the heat sources 1024, the ratio of actinic radiation sources 422 to the heat sources 1024 can be substantially different, such as 500:1 to 10:1. The ratio of actinic radiation sources to the heat sources may be greater than or less than the values described herein.

Many alternative implementations for the systems and equipment may be used. The number of each type of station can be different from what is illustrated in order to increase throughput or as needed or desired for a particular physical design of an apparatus or station within the apparatus. For example, more than one planarization head station 125 may be used. When at least two planarization head stations are used, (1) all planarization head stations may be used between dispensing and curing operations, or (2) at least one planarization head station may be used between dispensing and curing operations and at least one other planarization head station may be used after one a curing operation. For each type of station, the number and location of the stations can be tailored for a particular application. Each planarization head station shares a positioning stage with at least one heated radiation exposure station.

Functionality described with respect to a particular station may be performed by a different station. As was previously addressed, functionality associated with the planarization head station 125 may be incorporated into the dispense station 123 or the radiation exposure station 126, and thus, the planarization head station 125 may not be needed. In another implementation, exposure to actinic radiation may occur at more than one temperature. In this implementation, the heated radiation exposure station 126 may heat the pre-cured layer to a first temperature prior to curing and an optional radiation exposure station may heat the cured planarization layer to a second temperature where the further curing is performed. In a further implementation, different exposures to actinic radiation may be performed within the same radiation exposure station. For example, within the same radiation station, a radiation exposure at a lower temperature may be performed, the substrate and pre-cured layer are heated to a higher temperature, and the substrate and the pre-cured layer are exposed to actinic radiation at the higher temperature. Before exposing the next substrate and pre-cured layer, the radiation exposure station may be cooled to be closer to the lower temperature. However, the cooling may adversely affect system throughput, or a greater number of radiation exposure stations may be used to keep the system throughput unchanged. After reading this specification, skilled artisans will be able to determine how many types and the number of radiation exposure stations to use.

More or fewer apparatuses and the selection of which stations are within each apparatus can be tailored for a particular application. The stations 123, 125, and 126 may be within the same apparatus to reduce process variability. The optional curing stations may be in a different apparatus. The optional curing stations may be within the bake apparatus 201. Thermal insulation may be used between the optional radiation exposure stations and the bake stations 276, or the heated radiation exposure stations 126 may be sufficiently spaced apart from the bake stations 276, so that heat emitted by the bake stations 276 does not interfere with the temperature control within the heated radiation exposure stations 126. Thermal insulation may be used between the heated radiation exposure stations 126 and one or both of the dispense station 123 and the planarization head station 125. In a further implementation, the heated radiation exposure stations may be within their own apparatus and not shared with any of the stations 123, 125, and 276. In yet another implementation, the number of apparatuses may depend on the layout, facilities connections, or both within the room where the apparatuses are located. After reading this specification, skilled artisans will be able to the number, design, and location of apparatuses for a particular system.

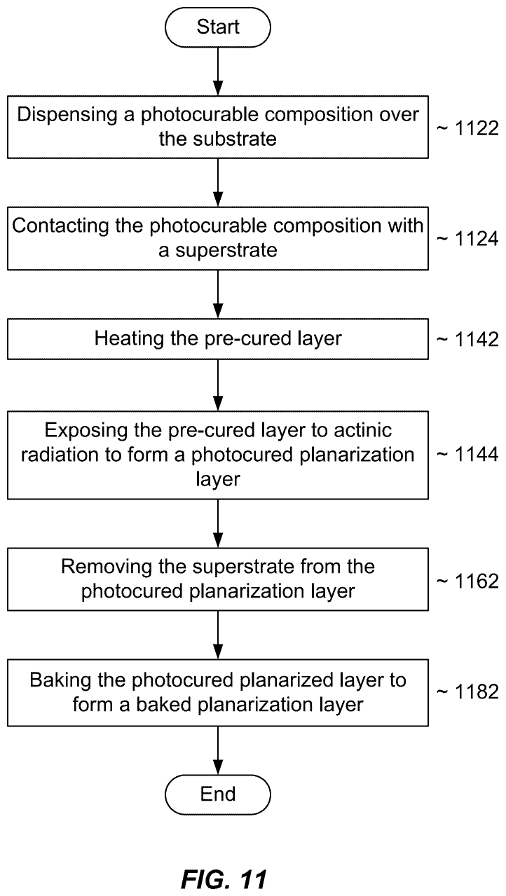

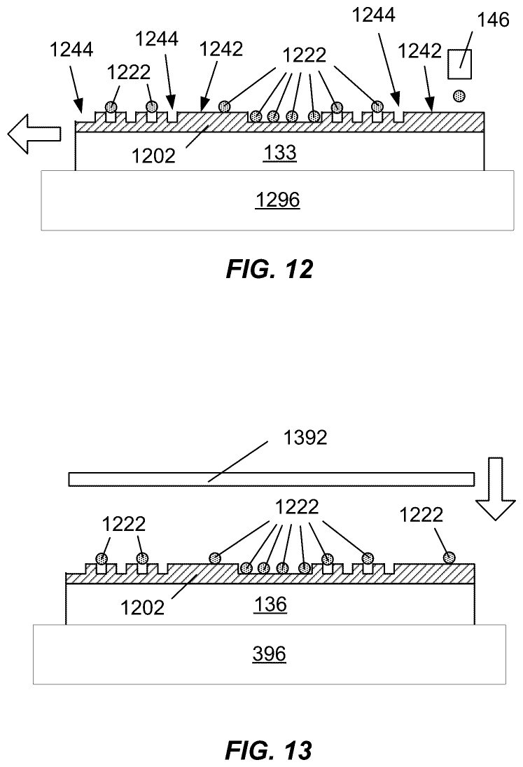

Attention is directed to methods of using the system 100 to form a baked planarization layer over a substrate. FIG. 11 includes a process flow diagram of a method that is described with respect to any system illustrated and described with respect to FIGS. 1 to 9. A particular process flow is described below in conjunction with the figures and is directed to an IAP process. Many different process flows can be used and still achieve the benefits using the concepts described herein. As used hereinafter, an unpatterned superstrate is referred to as a blank, and a patterned superstrate is referred to as a template. Other variants from the process flow are described later in this specification. At least some features within FIGS. 12 to 17, 27, and 28 are not drawn to scale in order to allow such and other features to be understood better with respect to the methods described.

Referring to FIGS. 1 and 12, the method can include transferring a substrate from the substrate pod 121 to the dispense station 123. The controller 150 or a local controller can transmit a signal for the substrate transfer tool 110 to remove the substrate 1202 from the substrate pod 121 and move the substrate 1202 to the dispense station 123. The substrate transfer tool 110 can place the substrate 1202 on the substrate chuck 133 within the dispense station 123.

The method can include dispensing a polymerizable composition over a substrate at block 1122 in FIG. 11. The polymerizable composition can include a polymerizable material and a photoinitiator. The polymerizable composition may or may not include a solvent. In a further implementation, the polymerizable composition can contain another additive. A non-limiting example of the other additive can be a surfactant, a dispersant, a stabilizer, an inhibitor, a dye, or a combination thereof.

Returning to the method and FIGS. 1 and 12, the dispense head 146 dispenses droplets 1222 of the polymerizable composition over the exposed surface of the substrate 1202 as illustrated in FIG. 12. During a dispensing operation, the substrate chuck 133 can be coupled to a positioning stage 1296 that is adapted to move the substrate chuck 133 (illustrated by the arrow adjacent to the substrate 1202 in FIG. 12) during a dispensing operation. In another implementation, the dispense head 146 moves while the substrate chuck 133 is stationary, and in a further implementation, both substrate chuck 133 and the dispense head 146 move during dispensing.

The substrate 1202 can have an exposed surface having a projection that lies at a relatively higher elevation as compared to an adjacent recession. In FIG. 12, the exposed surface of the substrate 1202 has protrusions 1242 and recessions 1244. The substrate 1202 has a local area with a relatively higher areal density of protrusions 1242 as compared to the recessions 1244 and another local area with a relatively higher areal density of recessions 1244 as compared to the protrusions 1242. A lower areal density of the polymerizable composition is dispensed where protrusions 1242 occupy a relatively larger fraction of a local area, and a higher areal density of the polymerizable composition is dispensed where recessions 1244 occupy a relatively larger fraction of a different local area. In practice, the exposed surface of the substrate 1202 is significantly more complex than illustrated in FIG. 12 and may not be limited to only two elevations. The exposed surface of the substrate 1202 in FIG. 12 is simplified to aid in understanding the concepts described herein.

The controller 150 or a local controller can transmit signals so that the dispense head 146, the positioning stage 1296 coupled to the substrate chuck 133 (when the substrate chuck 133 is coupled to the positioning stage), or both move in a desired direction and velocity, and the dispense head 146 dispenses the droplets 1222 of the polymerizable composition at a desired rate in order to achieve proper local areal densities of the polymerizable composition along the exposed surface of the substrate 1202.

Referring to FIGS. 1, 12, and 13, after the droplets 1222 of the polymerizable composition are dispensed, the substrate 1202 and the droplets 1222 of the polymerizable composition can be moved from the dispense station 123 to the planarization head station 125. The controller 150 or a local controller can transmit a signal for the substrate transfer tool 110 to move the substrate 1202 and the droplets 1222 of the polymerizable composition from the dispense station 123 to the planarization head station 125 and onto the substrate chuck 136 coupled to the positioning stage 396. Referring to FIGS. 1 and 13, the positioning stage 396 and the substrate chuck 136 are moved from the heated radiation exposure station 126 to the planarization head station 125 if the positioning stage 396 and the substrate chuck 136 were not in the planarization head station 125 before the substrate 1202 and the droplets 1222 are transferred to the planarization head station 125.

The process further includes contacting the polymerizable composition with a superstrate at block 1124 in FIG. 11. Referring to FIG. 12, a superstrate 1392 can be used to aid in forming a pre-cured layer from the droplets 1222 of the polymerizable composition. In an implementation, the superstrate 1392 can be a blank with a planar bottom surface facing the substrate 1202 and the droplets 1222. The planarization head station 125 can include a superstrate handler (not illustrated) that can be used to move and position the superstrate 1392. In the same or different implementation, the superstrate 1392 can be held by a planarization head within the radiation exposure station 126.

The superstrate 1392 has a transmittance of at least 70%, at least 80%, at least 85%, or at least 90% for actinic radiation used to photocure the polymerizable composition. The superstrate 1392 can include a glass-based material, an organic polymer, a siloxane polymer, a fluorocarbon polymer, a sapphire, a spinel, silicon, metal, another similar material, or any combination thereof. The glass-based material can include soda lime glass, borosilicate glass, alkali-barium silicate glass, aluminosilicate glass, quartz, fused-silica, or the like. In an implementation, the actinic radiation can be ultraviolet radiation, and a glass-based material can be used for the superstrate 1392. The superstrate 1392 can have a thickness in a range from 30 microns to 2000 microns. The contacting surface of the superstrate 1392 can have a surface area that is at least 90%, 95%, 96%, 97%, or 99% of the area of the substrate 1202 and may have a surface area that is the same or larger than the substrate 1202. The superstrate 1392 may have a gas absorbing layer that has a low surface energy relative to the photocured planarization layer that reduces the separation force between the superstrate and the photocured planarization layer.

The contacting surface of the superstrate 1392 has a two-dimensional shape including a circle, an ellipse, a rectangle (including a square), a hexagon, or the like. The two-dimensional shape can be the same as an outer shape of the substrate 1202. For example, both can be circles. In the implementation illustrated in FIG. 13, the contacting surface does not have any recessions and protrusions.

Referring to FIGS. 1, 13, and 14, the controller 150 or a local controller can transmit a signal for the superstrate 1392 and the droplets 1222 to move closer and contact each other. The superstrate 1392 may be moved, the substrate chuck 136 may be moved, or both the superstrate 1392 and the substrate chuck 136 can be moved. As the superstrate 1392 contacts droplets 1222 of the polymerizable composition, and the droplets 1222 can coalesce to form a pre-cured layer 1422 of the polymerizable composition. The upper surface 1412 of the pre-cured layer 1422 conforms to the bottom, contacting surface of the superstrate 1392.

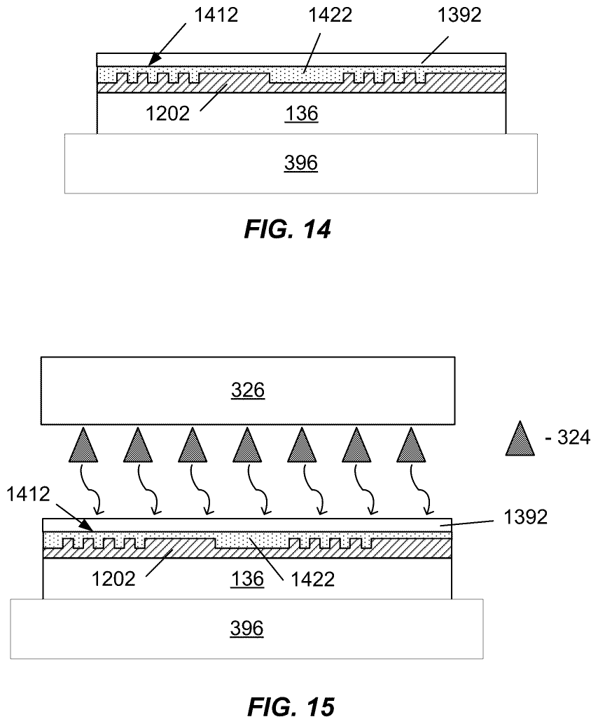

Referring to FIGS. 1 and 14, the positioning stage 396 coupled to the substrate chuck 136 can transfer the substrate 1202 and the pre-cured layer 1422 from the planarization head station 125 to the heated radiation exposure station 126. The controller 150 or a local controller can transmit a signal for the positioning stage 396 to move the substrate chuck 136, the substrate 1202, and the pre-cured layer 1422 from the planarization head station 125 to the radiation exposure station 126.

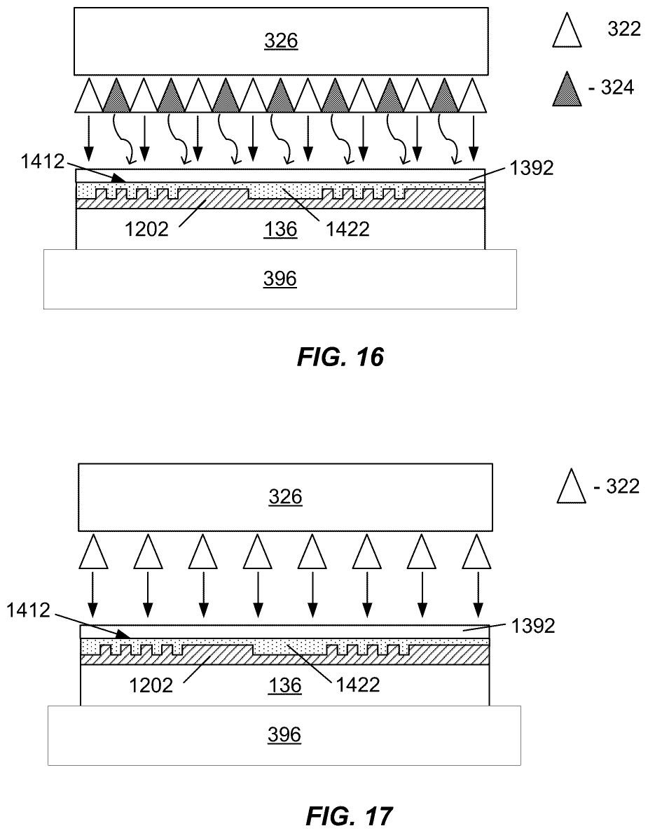

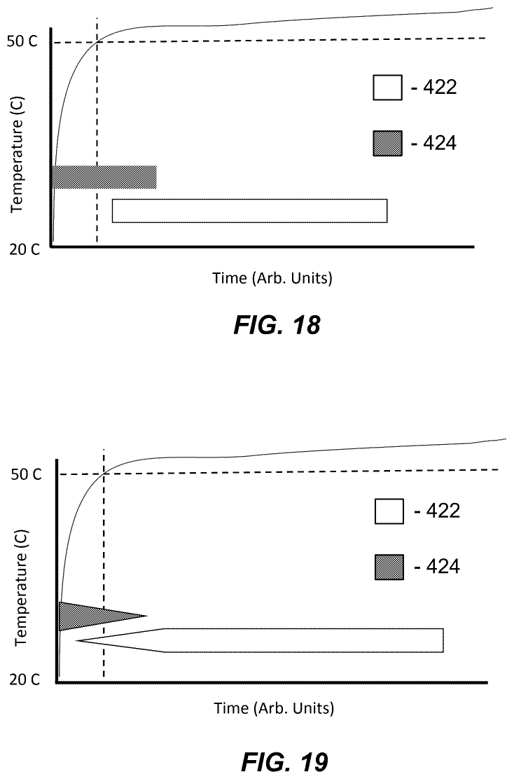

The process further includes heating the pre-cured layer at block 1142 and exposing the pre-cured layer to actinic radiation to form a photocured planarization layer at block 1144 in FIG. 11. Referring to FIGS. 15 to 17, the heat sources 424 can be activated and the actinic radiation sources 422 can be deactivated to emit heat 324 that reaches the workpiece including the substrate 1202, the pre-cured layer 1422 and the superstrate 1392 (FIG. 15); the actinic radiation sources 422 and the heat sources 424 can be activated to emit actinic radiation 322 and heat 324 that reaches the workpiece (FIG. 16); and the actinic radiation sources 422 can be activated and the heat sources can be deactivated to emit actinic radiation 322 that reaches the workpiece (FIG. 17). Heating may be initiated before, at the same time, or after initiating exposing the pre-cured layer 1422 to actinic radiation. The timing for activating, deactivating, and power levels during activation for the actinic radiation sources 422 and the heat sources 424 are described later in this specification with respect to FIGS. 18 to 26. The description below addresses considerations for heating and exposing to actinic radiation the pre-cured layer 1422 before addressing the timing diagrams.

Heating the pre-cured layer 1422 can help to reduce the amount of thickness change that occurs due to photocuring and baking the polymerizable composition within the pre-cured layer 1422. The temperatures to be achieved for the pre-cured layer 1422 may depend on whether or not heating is terminated or reduced before the pre-cured layer 1422 is exposed to actinic radiation or whether or not heating is to continue during exposure to actinic radiation. If the heating is terminated before exposing the pre-cured layer 1422 to actinic radiation, the targeted temperature may be higher than desired radiation exposure temperature to account for some cooling between the time heating is terminated and until some time during the subsequent exposure, such as the beginning, middle, end, or another time during the exposure. If heating continues during the exposure, the targeted temperature may or may not be the same as the desired radiation exposure temperature.

The desired radiation exposure temperature is greater than room temperature may be at most 95° C., at most 85° C., or at most 80° C. The desired radiation exposure temperature can be in a range from 25° C. to 95° C., 30° C. to 85° C., or 35° C. to 80° C. The targeted temperature of the heating may be the same or a few degrees warmer than the desired radiation exposure temperature. The targeted temperature can be in a range from 25° C. to 98° C., 30° C. to 88° C., or 35° C. to 83° C. The desired radiation exposure temperature can be set based on baking information including at least one of: the baking temperature; a desired baking temperature; the composition of the pre-cured layer; the experimentally determined relative thickness change of the pre-cured layer after baking; the experimentally determined relative thickness change of the photocured planarization layer after baking; and the planarization performance after baking.

During heating, a temperature sensor can be used to monitor the temperature of the pre-cured layer 1422 by measuring the temperature of the pre-cured layer 1422, the substrate 1202, or the superstrate 1392. Each of the substrate 1202 and the superstrate 1392 has substantially more mass than the pre-cured layer 1422, and the temperature of the substrate 1202 or the superstrate 1392 can be used for the temperature of the pre-cured layer 1422. The controller 150 or a local controller can receive temperature data from the temperature sensor, and the controller 150 or the local control can transmit a signal for the heat sources 424 to heat the substrate 1202 and the pre-cured layer 1422 to the targeted temperature. The signal can include activation information and, if the heat sources 424 can operate at more than one power lever, power level information. After the pre-cured layer 1422 reaches the targeted temperature, the controller 150 or a local controller can transmit a signal for the heating sources 424 to terminate or continue heating the pre-cured layer 1422 at the targeted temperature.

Regarding exposure of the pre-cured layer to actinic radiation to form a photocured planarization layer, for a particular polymerizable composition, the memory 152 (FIG. 1) can include information regarding a targeted wavelength or a targeted range from wavelengths for the actinic radiation, a targeted total dose or a targeted range from total doses to be used for the polymerizable composition, a dose used when exposing the pre-cured layer 1422 to actinic radiation to form the photocured planarization layer, or other data related to exposing the polymerizable composition to actinic radiation. Such information can be used by the controller 150 or a local controller to determine parameters for exposing the pre-cured layer 1422 to the actinic radiation. During curing, the polymerizable composition can be at a desired radiation exposure temperature+/−3° C. The temperature at the time of the heated radiation exposure is referred to herein as the actual radiation exposure temperature. The actual radiation exposure temperature can be at or near the desired radiation exposure temperature. The actual radiation exposure temperature can be any of the targeted temperatures and tolerances previously described.

The controller 150 or a local controller can receive a signal from the temperature sensor or a derivative of such signal and determine if the temperature is at or within a tolerance (for example, +/−5° C., +/−2° C., +/−1° C., or +/−0.5° C.) of the desired radiation exposure temperature. When the temperature is at or within a tolerance of the desired radiation exposure temperature, the controller 150 or a local controller can transmit a signal for an actinic radiation source 422 to be activated as illustrated in FIG. 16 or 17. The signal can include activation information and, if the actinic radiation sources 422 can operate at more than one power lever, power level information.

Most of the exposure to actinic radiation may occur when the pre-cured layer 1422 is at or above 50° C. The timing of when the actinic radiation sources 422 and the heat sources 424 are activated and deactivated and power levels if the sources can operate at more than one power level are better understood with respect to the timing diagrams in FIGS. 18 to 26. In FIGS. 18 to 26, the power level for radiation or heat emitted is proportional to the vertical dimension of the actinic radiation 322 or the heat 324 as illustrated in the timing diagram. A rectangle represents a constant power level during a time period, and a triangle represents a power level that decreases or increases as a function of time.

In FIG. 18, the heat sources 424 are activated to emit heat when the actinic radiation sources 422 are deactivated. The actinic radiation sources 422 are activated to emit actinic radiation after heating begins. Both the actinic radiation sources 422 and the heat sources 424 are activated during a time period and then the heat sources 424 are deactivated. After a further time period, the actinic radiation sources 422 are deactivated.

FIG. 19 can be used with actinic radiation sources 422 and heat sources 424 that can operate at more than one power level. In FIG. 19, the heat sources 424 are activated to emit heat, and the power level of the heat sources 424 decreases as a function of time. The actinic radiation sources 422 are activated to emit actinic radiation at the time of or shortly after the heat sources 424 are activated. The power level for the actinic radiation sources 422 increases as a function of time until a constant power level is achieved. The actinic radiation sources 422 remain at the constant power level for another time period before the actinic radiation sources 422 are deactivated. During a particular time period as illustrated in FIG. 19, the power level of heat sources 424 supplied decreases while the power level of actinic radiation sources 422 increases.

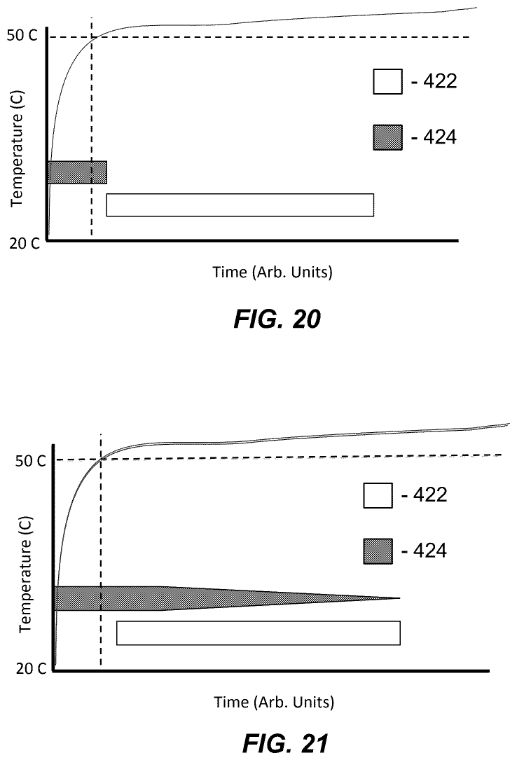

FIG. 20 is similar to FIG. 18, except that both the actinic radiation sources 422 and heat sources 424 are not activated during any particular time period. The actinic radiation sources 422 are activated at the time of or after the heat sources 424 are deactivated.

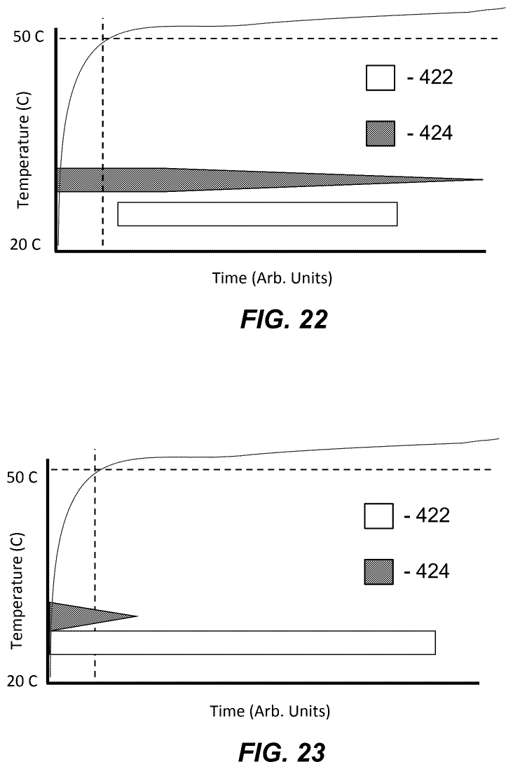

FIGS. 21 and 22 are similar to FIG. 18, except that the power level of the heat sources decreases in FIG. 21 at about the same time the heat sources 424 in FIG. 18 are deactivated. In FIG. 21, the power level of the heat sources 424 can be decreased to zero or deactivated at the time the actinic radiation sources 422 are deactivated. FIG. 22 is similar to FIG. 21 except the power level of the heat sources 424 can be decreased to zero or deactivated after the actinic radiation sources 422 are deactivated. In another implementation (not illustrated), the power level of the heat sources 424 can be decreased to zero or deactivated before the actinic radiation sources 422 are deactivated.

In FIG. 23, the heat sources 424 are activated to heat the substate which causes the pre-cured layer 1422 to heat up, and the power level of the heat sources 424 decreases as a function of time. The actinic radiation sources 422 are activated to emit actinic radiation at the time of or shortly after the heat sources 424 are activated. The power level for the actinic radiation sources 422 remains constant until the actinic radiation sources 422 are deactivated.

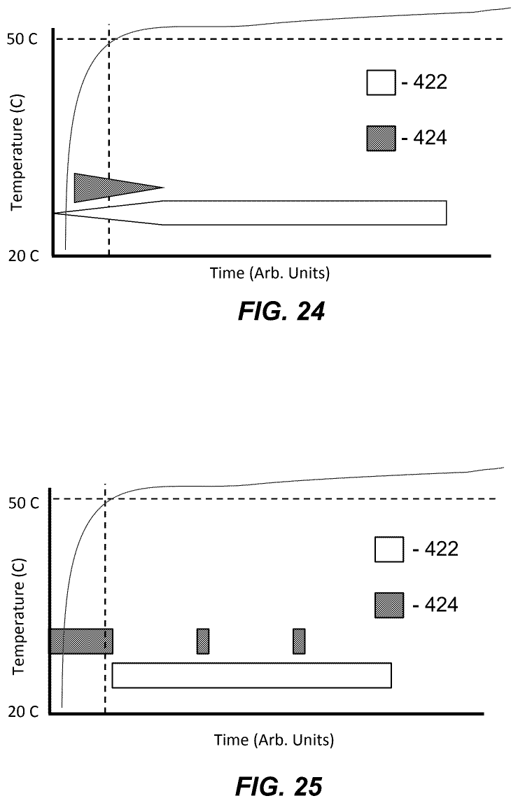

FIG. 24 is similar to FIG. 19 except that the actinic radiation sources 422 are activated before the heat sources 424 are activated. Further, during the power transition time period, the power level of the actinic radiation sources 422 increases more gradually as a function of time as compared to FIG. 19. Thus, exposing the pre-cured layer 1422 to actinic radiation can start before heating begins. Heating the pre-cured layer 1422 helps to reduce an amount of thickness change, usually shrinkage, that can occur during exposure to actinic radiation and baking. A dosage of actinic radiation emitted from the actinic radiation sources 422 is below a threshold when the polymerizable composition is below the targeted temperature. Thus, before the heat sources 424 are activated, the dose of actinic radiation emitted from the actinic radiation sources 422 can be at most 60% of the total dose of actinic radiation during the exposure operation. To help keep the thickness change relatively low, at most 9%, 5%, or none of the total dose occurs before the heat sources 424 are activated.

The heat sources 424 may be designed to work at only one power level. FIG. 25 is similar to FIG. 20 except that, after initial heating, the heat sources 424 are activated and deactivated for relatively short time periods (hereinafter, “heat pulses”) to help keep the temperature of the pre-cured layer 1422 relatively more constant than if the heat pulses were not used. The number of heat pulses can be more or fewer than illustrated. In the same or different implementation, the time period of the time pulses or time between the heat pulses can be different from what is illustrated in FIG. 25. The heating operation as illustrated in FIG. 25 can be used with heat sources 424 that can operate at more than one power level, even though the heat sources 424 do not need to be at different power levels when the heat sources 424 are activated.

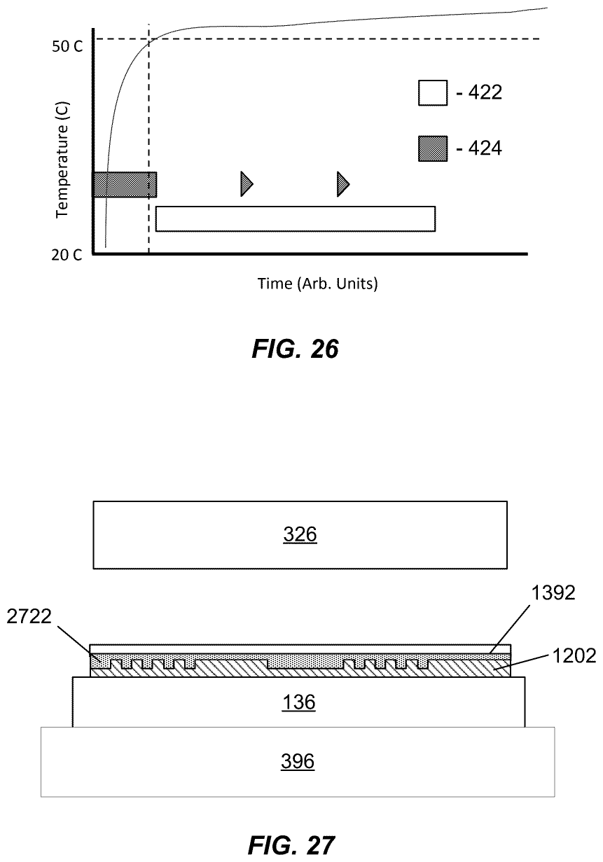

The heating operation in FIG. 26 can be used when the heat sources 424 can operate at more than one power level. FIG. 26 is similar to FIG. 25 except that the heat pulses have power levels for the heat sources 424 that change as a function of time. In FIG. 26, during the heat pulses, the power levels of the heat sources 424 decrease as a function of time. In another implementation, during one or both of the heat pulses, the power level of the heat sources 424 may increase as a function of time, or the power level may be substantially constant for part of the heat pulse before the power level decreases, after the power level increases, or a combination thereof.

Regarding FIGS. 25 and 26, skilled artisans will be able to determine whether or not heat pulses are used, the number of heat pulses, the time duration of the heat pulses, power levels of the heat pulses, and time between heat pulses for a particular application.

Energy from the exposure to actinic radiation forms the photocured planarization layer 2722 illustrated in FIG. 27. The energy polymerizes the polymerizable material to form polymer material or covalent bonds with neighboring molecules to form a cross-linked material. The polymer material can be a single polymer compound or may be a co-polymer. The exposure to the actinic radiation during the heated radiation exposure substantially polymerizes but may not fully polymerize the polymerizable material within the photocured planarization layer 2722. In an implementation, no further exposure to actinic radiation may occur. Further polymerization may occur during a post-exposure baking of the photocured planarization layer 2722 due to thermal curing.

After the photocured planarization layer 2722 is formed, the superstrate 1392 can be removed. Referring to FIGS. 1 and 27, in an implementation, the superstrate 1392 can be removed within the planarization head station 125. The controller 150 or a local controller can transmit a signal for the positioning stage 396 to move from the heated radiation station 126 to the planarization head station 125.

The method can include removing the superstrate from the photocured planarization layer at block 1162 in FIG. 11. The polymerizable composition can include an internal mold release agent that remains in the photocured planarization layer 2722 after polymerization. The internal mold release agent can help to reduce the likelihood of damaging the photocured planarization layer 2722 or removing part or all of the photocured planarization layer 2722 when removing the superstrate 1392. The superstrate 1392 can also include a mold release agent. The controller 150 or a local controller can transmit a signal for the planarization head 135 to remove the superstrate 1392 from the photocured planarization layer 2722.

In another implementation, the superstrate 1392 can be removed within the heated radiation station 126. Thus, the positioning stage 396 may remain within the heated radiation station 126 while the superstrate 1392 is removed.

The method can include moving the substrate 1202 and the photocured planarization layer 2722 from the cure apparatus 101 to the bake apparatus 201. Referring to FIG. 1, the controller 150 or a local controller can transmit a signal for the substrate transfer tool 110 to remove the substrate 1202 and the photocured planarization layer 2722 from the planarization head station 125 and move the substrate 1202 and the photocured planarization layer 2722 to the substrate pod 121 or another substrate pod. The substrate pod 121 or the other substrate pod can be moved to the bake apparatus 201 for further processing. In another implementation, the substrate 1202 and photocured planarization layer 2722 can be moved to the substrate pod 271 in FIG. 2. The substrate transfer tool 210 can place the substrate 1202 on a substrate chuck 286 within one of the post-exposure bake stations 276.

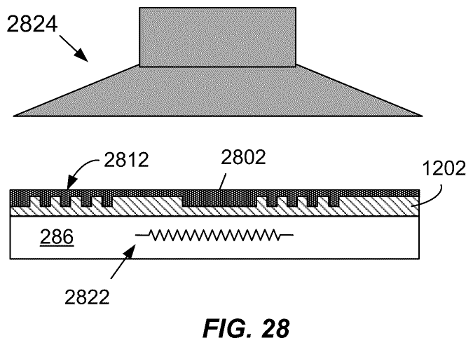

The method can include baking the photocured planarization layer to form a baked planarization layer at block 1182 in FIG. 11. During the baking operation, the material within the photocured planarization layer 2722 can further polymerize, cross-link, or both. The baking operation can also help remove a relatively volatile component, if present, from the photocured planarization layer 2722 when forming a baked planarization layer 2802 in FIG. 28. The baked planarization layer 2802 has an upper surface 2812.

A heating means within the post-exposure bake station 276 is used to heat the photocured planarization layer 2722 (FIG. 27) to form the baked planarization layer 2802 (FIG. 28). The heating means can include a resistive heating element, a radiative heating element, or a gas flow system (for example, a heater and a fan) that provides a heated gas for convection heating. FIG. 28 illustrates a resistive heating element 2822 within the substrate chuck 286 and a radiative heating element 2824 positioned over the substrate chuck 286. The heating means provides heat at a temperature higher than the temperature used for the heated radiation exposure operation. The baking temperature can be at least 300° C., at least 325° C., or at least 350° C. The baking temperature should not be so high as to cause significant decomposition or another adverse effect to the baked planarization layer 2802. The baking temperature can be at most 500° C., at most 450° C., or at most 400° C. The baking temperature can be a value between any of the minimum and maximum numbers noted above, for example, in a range from 300° C. to 500° C., 300° C. to 450° C., or 300° C. to 400° C. In a particular implementation, the baking temperature can be in a range from 350° C. to 400° C.

A soak time is the time the substrate 1202 and overlying polymer layer is at the baking temperature. The soak time needs to be sufficient to achieve a needed or desired amount of further polymerization or cross-linking, reduce the amount of a volatile component within the polymer layer to a desired amount, or both. The soak time can be at least 0.25 minute, at least 1 minute, or at least 3 minutes. After a long enough time, further exposure to the baking temperature may not sufficiently improve the polymer layer (a sufficient amount of polymerization or cross-linking has occurred, a remaining amount of the volatile component is low enough to not cause a problem during subsequent processing, etc.) or may start to cause an adverse effect, such as roughening the upper surface 2812 of the baked planarization layer 2802, possible delamination of the baked planarization layer 2802 from the substrate 1202, or the like. The soak time may be at most 30 minutes, at most 20 minutes, or at most 15 minutes. The soak time can be a value between any of the minimum and maximum numbers noted above, for example, in a range from 0.25 minute to 30 minutes, 1 minute to 20 minutes, or 3 minutes to 15 minutes.

The baking operation can be performed using a gas. The gas can include a material that is relatively inert to the photocured planarization layer 2722 and the baked planarization layer 2802. The material can include N₂, CO₂, a noble gas (Ar, He, or the like), or a mixture thereof. The gas may not include an oxidizing material, for example O₂, O₃, N₂O, or the like, or may include no more than 2 mol % or no more than 0.5 mol % of the oxidizing material.

As illustrated, the post-exposure bake stations 276 are adapted to process a single substrate at a time. In another implementation, the post-exposure bake stations 276 can be adapted to process a plurality of substrates during the same baking operation. The post-exposure bake stations 276 may include a cassette or another suitable substrate container or be capable of receiving the cassette or the other suitable substrate container, where the cassette or the other suitable substrate container can hold a plurality of substrates.

The memory 252, a database, or another memory outside the post-exposure bake apparatus 201 can include information regarding the composition of or polymer precursor used to form the photocured planarization layer 2722, a desired baking temperature, a desired soak time to form the baked planarization layer 2802, or a combination thereof. Referring to FIG. 2, the controller 250 or a local controller can transmit a signal for the post-exposure bake station 276 to flow the inert gas within the post-exposure bake station 276 and control the heating means to maintain the substrate 1202 and the photocured planarization layer 2722 at or within an allowable tolerance of the desired baking temperature for the soak time. The allowable tolerance may be +/−10° C., +/−5° C., or +/−2° C. of the desired baking temperature. Referring to FIG. 28, during heating, the controller 250 or a local controller can receive temperature data from a temperature sensor (not illustrated) within the substrate chuck 286 or a proximity temperature sensor (not illustrated). The temperature sensor within the substrate chuck 286 can be located where it can be in contact with or close proximity (for example, within 1 mm) of the substrate 1202 when the substrate is located over substrate chuck 286. Referring to FIGS. 27 and 28, the proximity temperature sensor can receive near infrared radiation from the substrate 1202 or the photocured planarization layer 2722 to determine a temperature of the substrate 1202 or the photocured planarization layer 2722.

The controller 250 or the local control can transmit a signal for the heating means, such as the resistive heating element 2822 or the radiative heat element 2824, to heat the substrate 1202 and the photocured planarization layer 2722 to the baking temperature or to maintain the temperature within the post-exposure bake station 276 at the baking temperature.

After the soak time, the controller 250 or a local controller can transmit a signal for the heating means to be deactivated and for substrate transfer tool 210 to remove the substrate 1202 and baked planarization layer 2802 from the post-exposure bake station 276. The substrate 1202 and baked planarization layer 2802 can be moved by the substrate transfer tool 210 to a chill plate to reduce the temperature of the substrate 1202 and the baked planarization layer 2802 before the substrate 1202 and baked planarization layer 2802 are moved back to the substrate pod 271. After chilling is completed, the controller 250 or a local controller can transmit signal for the substrate 1202 and baked planarization layer 2802 to be moved to the substrate pod 271. In an alternative implementation, the system 100 does not include the additional substrate transfer tool 210 and the substrate pod 271 and the substrate transfer tool 110 is adapted to transfer at least one substrate having a photocured planarization layer to the post-exposure bake station 276, the substrate transfer tool may then move the substrate with the baked planarization layer 2802 to a substrate pod 121.

After reading this specification, skilled artisans will appreciate that many system configurations and processing options are available without deviating from the concepts described herein. Skilled artisans will be able to determine a particular system configuration and a particular method to use to meet the needs or desires for a particular application.

The process described above can be used in forming a planarization layer from a polymerizable composition. The process described above can be integrated as part of a manufacturing method of making an article. The article can be an electrical circuit element, an optical element, a microelectromechanical system (MEMS), a recording element, a sensor, a mold, an electro-optical element, a microfluidic element, a piezoelectric element, a thermoelectric element, a spintronic element, a superconducting element, an integrated circuit, or the like. The integrated circuit may be a solid state memory (such as a dynamic random access memory (DRAM), a static random access memory (SRAM), a flash memory, or a magnetoresistive random access memory (MRAM)), a microprocessor, a microcontroller, a graphics processing unit, a digital signal processor, a field programmable gate array (FPGA) a semiconductor element, a power transistor, a charge coupled-device (CCD), an image sensor, an application specific integrated circuit (ASIC), or the like.

The method can further include subjecting the substrate 1202 and the baked planarization layer 2802 to other processes for device (article) fabrication, including, for example, curing, oxidation, layer formation, deposition, doping, additional planarization, lithography, etching, formable material removal, dicing, bonding, and packaging, and the like. The substrate may be processed to produce a plurality of articles (devices), for example, the substrate may be a semiconductor wafer.

In an alternative implementation, more than one radiation exposure may be performed. For example, the other radiation exposure may be performed at room temperature before the heated radiation exposure previously described. The other radiation exposure may be performed in the radiation exposure station 126 before heating for the heated radiation exposure or may be performed in a separate radiation exposure station. In another example, the other radiation exposure may be performed between the heated radiation exposure and the baking operation. After reading this specification, skilled artisans will be able to determine the number of radiation exposure, environment conditions (e.g., temperature and areal radiation density), and the number of radiation exposure stations to be used for a particular application.

Implementations as described herein can allow more flexibility regarding heating and exposure operations and may allow a system 100 to occupy less area. Actinic radiation sources and heat sources can be integrated into an array within a radiation head assembly. Separate stations for heating a pre-cured layer of a polymerizable composition and exposing the pre-cured layer is not required. The array of actinic radiation sources and heat sources allow greater flexibility with respect to heating and exposing to actinic radiation the pre-cured layer. Heat sources can be activated before, at the same time of, or after activating the actinic radiation sources. The actinic radiation sources can be deactivated after, at the same time of, or before deactivating the heat sources. After initial heating, heat pulses can be used to help maintain the actual temperature of the pre-cured layer within a narrower range as compared to heat pulses not being used. The actinic radiation sources, the heat sources, or the actinic radiation sources and heat sources may be adapted to operate at more than one power level. Thus, the amount of actinic radiation, heat or both may be changed as a function of time.

Note that not all of the activities described above in the general description or the examples are required, that a portion of a specific activity may not be required, and that at least one further activity can be performed in addition to those described. Still further, the order in which activities are listed is not necessarily the order in which they are performed.

Benefits, other advantages, and solutions to problems have been described above with regard to specific implementations. However, the benefits, advantages, solutions to problems, and any feature(s) that can cause any benefit, advantage, or solution to occur or become more pronounced are not to be construed as a critical, required, or essential feature of any or all the claims.

The specification and illustrations of the implementations described herein are intended to provide a general understanding of the structure of the various implementations. The specification and illustrations are not intended to serve as an exhaustive and comprehensive description of all of the elements and features of apparatus and systems that use the structures or methods described herein. Separate implementations can also be provided in combination in a single implementation, and conversely, various features that are, for brevity, described in the context of a single implementation, can also be provided separately or in any subcombination. Further, reference to values stated in ranges includes each and every value within that range. Many other implementations can be apparent to skilled artisans only after reading this specification. Other implementations can be used and derived from the disclosure, such that a structural substitution, logical substitution, or another change can be made without departing from the scope of the disclosure. Accordingly, the disclosure is to be regarded as illustrative rather than restrictive.

What is claimed is:

1. A system, comprising:
an array of:
at least one heat source adapted to emit heat at a peak heating wavelength and heat a stack including a superstrate, a substrate, and a polymerizable composition between the superstrate and the substrate; and
at least one actinic radiation source adapted to emit actinic radiation at a peak actinic radiation wavelength and at least photocure the polymerizable composition to form a photocured planarization layer,
wherein the peak heating wavelength is different from the peak actinic radiation wavelength.

2. The system of claim 1, wherein the peak heating wavelength is greater than the peak actinic radiation wavelength.

3. The system of claim 1, wherein the at least one heat source is adapted to emit heat at the peak heating wavelength in a range from 400 nm to 2500 nm.

4. The system of claim 3, wherein the peak heating wavelength is in a range from 400 nm to 1100 nm.

5. The system of claim 3, wherein the peak heating wavelength is in a range from 960 nm to 2500 nm.

6. The system of claim 3, wherein the at least one actinic radiation source is adapted to emit actinic radiation at the peak actinic radiation wavelength of at least 10 nm and less than 400 nm.

7. The system of claim 1, wherein the at least one heating source comprises a plurality of point heat sources.

8. The system of claim 1, wherein the at least one heating source comprises at least one resistive heating member.

9. The system of claim 1, further comprising:
a bake station adapted to bake the substrate and the photocured planarization layer; and
a controller adapted to receive bake station information and transmit a signal to the at least one heat source based on the bake station information.

10. The system of claim 1, further comprising:
a stage adapted to move the substrate; and
a first thermal isolation member disposed between the stage and the at least one heat source.

11. The system of claim 10, further comprising:
a cooling means adapted to reduce an amount of heat from the at least one heating source that reaches the stage, wherein the cooling means is disposed between the stage and the first thermal isolation member.

12. The system of claim 11, further comprising:
a second thermal isolation member, wherein the cooling means is disposed between the first thermal isolation member and the second thermal isolation member.

13. The system of claim 1, further comprising:
a stage adapted to move the substrate; and
a substrate chuck adapted to support the substrate and disposed between the stage and the at least one heat source.

14. The system of claim 13, wherein the substrate chuck comprises:
a cooling means adapted to reduce an amount of heat from the at least one heating source that reaches the stage.

15. The system of claim 14, wherein the substrate chuck further comprises:
a thermal isolation member to reduce an amount of heat from the at least one heating source that reaches the stage.

16. A method, comprising:
heating a stack with at least one heat source to a targeted temperature, wherein:
the at least one heat source emits heat at a peak heating wavelength,
the stack includes a substrate, a superstrate, and a polymerizable composition disposed between the substrate and the superstrate, and
an array includes:
the at least one heat source; and
at least one actinic radiation source; and
curing the polymerizable composition to form a photocured planarization layer, wherein curing is performed by exposing the stack to radiation emitted by the at least one actinic radiation source, and the at least one actinic radiation source emits actinic radiation at a peak actinic radiation wavelength,
wherein the peak heating wavelength is different from the peak actinic radiation wavelength.

17. The method of claim 16, wherein, during warming:
the stack is disposed on a substrate chuck,
the substrate chuck is coupled to a stage, and
a temperature of the stage is below a threshold when the stack is at the targeted temperature.

18. The method of claim 17, further comprising:
activating a cooling means that is disposed between the stack and the stage during heating, curing, or both.

19. The method of claim 17, further comprising:
moving the stack while the polymerizable composition is being cured and is at a temperature higher than an ambient temperature.

20. The method of claim 16, wherein a dosage of actinic radiation emitted from the at least one actinic radiation source is below a threshold when the polymerizable composition is below the targeted temperature.

21. The method of claim 16, further comprising:
baking the substate and the photocured planarization layer at a baking temperature to form a baked planarization layer,
wherein during curing, the polymerizable composition is at a desired radiation exposure temperature+/−3° C., wherein the desired radiation exposure temperature is selected at least in part on the baking temperature.
